(19) United States
(12) Patent Application Publication
(10) Pub. No.: US 2008/0107885 A1
(43) Pub. Date: May 8, 2008

(54) High-capacity, low-leakage multilayer dielectric stacks

(76) Inventors: S. Pamir Alpay, South Windsor, CT (US); Jospeh V. Mantese, Manchester, CT (US); Shan Zhong, Willimantic, CT (US)

Correspondence Address: McCARTER & ENGLISH, LLP;Attn.: Basam E. Nabulsi, Financial Centre, Suite 304A, 695 East Main Street, Stamford, CT, 06901-2103, US

(21) Appl. No.: 11/827,555

(22) Filed: Jul. 12, 2007

Related U.S. Application Data
(60) Provisional application No. 60/830,306, filed on Jul. 12, 2006.

(51) Int. Cl. B32B 9/00; H01L 21/00

(52) U.S. Cl. 428/220; 438/3; 428/702; 257/E21.001

(57) ABSTRACT

The present disclosure is directed to an exemplary method for designing, implementing, and making a high capacity low leakage multilayer stack for various electronic applications. In a particular embodiment, the multilayer stack is made up of a dielectric/ferroelectric/dielectric trilayer. This configuration has shown to have giant dielectric permittivity which is much higher than conventional gate dielectrics. The DE/FE interlayer exhibits strong interlayer coupling, yielding desired properties. In order to prevent leakage and loss while maintaining high capacity, certain parameters of each layer must exist. The present disclosure describes a method of quantitatively achieving these parameters through correlating critical fraction with dielectric constant. Moreover, this method can be used for scalability of electronic materials.

### CROSS-REFERENCE TO RELATED APPLICATIONS

The present application claims the benefit under 35 U.S.C. § 119(e) of U.S. Provisional Application No. 60/830,306, filed Jul. 12, 2006. The foregoing application is also hereby incorporated by reference in its entirety for all purposes.

### BACKGROUND

1. Technical Field

The present disclosure relates to systems and methods for designing, implementing, and making multilayer dielectric stacks for use in integrated circuit (IC) devices.

2. Background Art

The semiconductor industry trend is to scale down the size of devices while still improving performance, including good figures of merit (FOM) and low energy consumption. For example, the current solutions for dielectric gate materials of complementary metal-oxide-semiconductor (CMOS) transistors are to utilize Si₃N₄, SiOₓN_{y}, and Si—N/SiO₂ dielectrics, according to the most recent industry roadmaps. However, these plans are typically 3-4-year near-term solutions to address issues and ultimately post a limitation on scaling a device.

Many materials systems are currently under consideration as potential replacements for SiO₂ as the gate dielectric material for sub-0.1 μm complementary metal-oxide-semiconductor CMOS technology. A systematic consideration of the required properties of gate dielectrics indicates that the key guidelines for selecting an alternative gate dielectric include but are not limited to: (a) permittivity, band gap, and band alignment to silicon; (b) thermodynamic stability; (c) film morphology; (d) interface quality; (e) compatibility with the current or expected materials to be used in processing for CMOS devices; (f) process compatibility; (g) reliability; (h) trap states—slow and fast; (i) leakage characteristics; (j) breakdown strength; (k) cyclicity; and (l) fatigue. Many dielectrics appear favorable in some of these areas, but very few materials are promising with respect to all of these guidelines. A review of current work and literature in the area of alternate gate dielectrics is disclosed in Wilk et al. (See e.g. High-κ gate dielectrics: Current status and materials properties consideration, J. Appl. Phys. 89, 5243 (2001)). Based on reported results and fundamental considerations, the pseudo binary materials systems offer large flexibility and show the most promise toward successful integration into the expected processing conditions for future CMOS technologies, especially due to their tendency to form at interfaces with Si (e.g. silicates). These pseudo binary systems also thereby enable the use of other high-K materials by serving as an interfacial high-K layer. While work is ongoing, much research is still required, as it is clear that any material which is to replace SiO₂ as the gate dielectric faces a formidable challenge. The requirements for process integration compatibility are remarkably demanding, and any serious candidates will emerge only through continued, intensive investigation. Thus, understanding a relationship with the dielectric critical fraction and design parameters may serve as a more productive solution rather than dielectric material alternatives.

Significant interest in dielectric superlattices has developed over the last decade, fueled by the possibility of functional properties in superlattices being superior to those of compositionally equivalent solid solutions. As discussed in Corbett et al., experimentally, dielectric constants have frequently been observed to increase on decreasing superlattice wavelength. (See e.g. Enhancement of dielectric constant and associated coupling of polarization behavior in thin film relaxor superlattices, Appl. Phys. Lett. 79, 815 (2001)). Features also normally associated with relaxor electroceramics have been seen, such as the migration of Tₘ (the temperature at which dielectric constant is maximum) with frequency, strong dispersion of dielectric constant below Tₘ and broad temperature dependence of dielectric response.

While an enhancement in the dielectric constant can be rationalized in terms of Ising models, recent experimental work has noted a correlation with the onset of significant Maxwell-Wagner effects. (See e.g. D. O'Neill, R. M Bowman, and J M Gregg, Appl. Phys. Lett. 77, 1520 (2000), B. D. Qu, W. L. Zhong, and R. H. Prince, Phys. Rev. B 55, 11218 (1997), J Shen and Y Ma, Phys. Rev. B 61, 14279 (2000)). Modeling has shown that most of the features displayed by ferroelectric superlattices can be generated by Maxwell-Wagner considerations. The implication is that most of the unusual properties observed to date could be explained by defect-related transport. Nonetheless, work on the structural phase transformation behavior in KTaO₃/KNbO₃ superlattices indicates that genuine coupled behavior can occur. To date though, such interlayer coupling has not been clearly manifested in functional properties.

Additional studies have been made in the field identifying a relationship between dielectric response and ferroelectric materials including their significant coupling effects with dielectric materials. (See e.g. Kim et al., Large nonlinear dielectric properties of artificial BaTiO₃/SrTiO₃ super lattices, Appl. Phys. Lett. 80, 3581 (2002); Tsurumi et al., Artificial ferroelectricity in perovskite superlattices, Appl. Phys. Lett. 85, 5016 (2004); Kim et al., High-performance low-cost phase-shifter design based on ferroelectric materials technology, Electronic Letters, 40, No. 21, (2004); Shimuta et al., Enhancement ofremnant polarization in epitaxial BaTiO₃/SrTiO₃ superlattices with “asymmetric” structure, J. Appl. Phys. 91, 2290 (2002); and Lee et al., Strong polarization enhancement in asymmetric three-component ferroelectric superlattices, Nature 433, 395 (2005)).

The disclosed references describe finding empirical combinations that offer improved performance. However, they fail to disclose a method of designing and scaling a stack for implementation to relevant applications. A further limitation alleviated by the present disclosure is increased leakage and loss due to scaling and improper polarization of the conductive materials. Finally, the present disclosure suggests that when the dielectric of choice is SiO₂, one can retain all the benefits derived from a good oxide-semiconductor interface, while dramatically improving capacitance density. Thus, a need exists in the art for an improved configuration and method of making multilayer stacks that increase dielectric response while eliminating leakage and loss.

### SUMMARY

The present disclosure provides for exemplary systems, devices, assemblies and methods for designing a high capacity low-leakage stack including a multilayer stack having at least a first dielectric layer defining a thickness parameter h₂ coupled with at least a first ferroelectric layer defining a thickness parameter h₁. The dielectric layer includes a dielectric material and the ferroelectric layer includes a ferroelectric layer. The multilayer stack defines a thickness parameter h such that h=h₁+h₂. An exemplary method according to the present disclosure includes the steps of selecting a dielectric material having a dielectric constant and designing a stack by correlating the dielectric constant with a critical fraction α. The critical fraction α is determined by the expression α=h₂/h.

In an exemplary embodiment, the multilayer stack is a trilayer including two dielectric layers with the ferroelectric layer coupled therebetween. Both dielectric layers can have thickness parameter h₂. In a further exemplary embodiment associated with the present disclosure, the multilayer stack is positioned in between a first and second electrode layer. Direct contact between the ferroelectric layer and at least one of the electrode layers should be avoided and/or eliminated. The multilayer stack can be grown on any substrate material used in the stack application.

Dielectric materials associated with the present disclosure can be selected from the group consisting of: SrTiO₃ (ST), SiO₂, Si₃N₄, Al₂O₃, Y₂O₃, La₂O₃, Ta₂O₅, TiO₂, HfO₂, ZrO₂, and combinations therein. Exemplary applications of the multilayer stack can include, but are not limited to, (Dielectric Random Access Memories) DRAMs, on chip capacitors, high frequency strip lines, high frequency waveguides, Micro-optical Electromechanical Systems (MOEMS), Ferroelectric Random Access Memory elements (FeRAMS), and integrated circuit (IC) elements. FeRAMS are also commonly referred to as FRAMS and it should be understood that these terms can be used interchangeably. An exemplary method according to the present disclosure may be used to design a multilayer stack capable of giant dielectric permittivity. The dielectric/ferroelectric layers can advantageously exhibit strong interlayer coupling properties. In a preferred embodiment, the disclosed method correlates α and the dielectric constant of the chosen dielectric material so as to be suitable for scaling design.

The present disclosure provides for a multilayer stack including: (a) at least a first dielectric layer including a dielectric material characterized by a dielectric constant, the dielectric layer defining a thickness h2; and (b) at least one ferroelectric layer including a ferroelectric material coupled to the dielectric layer, the ferroelectric layer defining a thickness h1. The dielectric constant yields a critical fraction a whereby h=h1+h2 and α=h2/h. The ferroelectric material is selected from the group consisting of BaTiO3, Ba1-xSrxTiO3 (0≦x≦0.25), PbTiO3, Pb1-xLaxTiO3, Pb1-xZrxTiO3 (0<x<0.40), Pb(Zn1/3Nb2/3)O3, Pb(Mg1/3Nb2/3)O3, Sr1-xBaxNb2O6, Bi4Ti3O12, Bi4-xLaxTi3O12, SrBi2Ta2O9, BaBi4Ti5O18, BiFeO3, KNO3, LiNbO3, LiTaO3, and combinations therein.

In an exemplary embodiment, the present disclosure provides for an electrical device including a multilayer stack having at least one dielectric layer including a dielectric constant defining a thickness h2 and at least one ferroelectric layer including a ferroelectric material coupled to the dielectric material defining a thickness h1. The dielectric constant yields a critical fraction α, whereby h=h1+h2 and α=h2/h. The multilayer stack exhibits a leakage loss of at most 0.01. The dielectric constant is polarized to a value of at least 500.

The present disclosure provides for an exemplary multilayer stack including: (a) at least a first dielectric layer including a dielectric material characterized by a dielectric constant, the dielectric layer defining a thickness h2; (b) at least a second dielectric layer including a dielectric material characterized by a dielectric constant, the dielectric layer defining a thickness h3; and (c) at least one ferroelectric layer including a ferroelectric material coupled and positioned therebetween the at least a first dielectric layer and the at least a second dielectric layer, the ferroelectric layer defining a thickness h1. The dielectric constants associated with each of the first dielectric layer and the second dielectric layer yield a critical fraction α, whereby h=h1+h2+h3 and 1−α=h1/h. The ferroelectric material is selected from the group consisting of BaTiO3, Ba1-xSrxTiO3 (0<x<0.25), PbTiO3, Pb1-xLaxTiO3, Pb1-xZrxTiO3 (0<x<0.40), Pb(Zn1/3Nb2/3)O3, Pb(Mg1/3Nb2/3)O3, Sr1-xBaxNb2O6, Bi4Ti3O12, Bi4-xLaxTi3O12, SrBi2Ta2O9, BaBi4Ti5O18, BiFeO3, KNO3, LiNbO3, LiTaO3, and combinations therein.

Additional features, functions and benefits of the disclosed systems and methods will be apparent from the description which follows, particularly when read in conjunction with the appended figures.

### BRIEF DESCRIPTION OF THE DRAWINGS

To assist those of ordinary skill in the art in making and using the disclosed systems and methods, reference is made to the appended figures, wherein:

FIG. 1(a) is a schematic of a free standing DE/FE/DE trilayer with top and bottom electrodes;

FIG. 1(b) is a schematic of a DE/FE/DE trilayer with top electrode grown on platinized Si substrate.

FIG. 2 is a graph illustrating the relationship between critical fraction and dielectric constant.

FIG. 3 is a chart illustrating the relationship between critical fraction and dielectric constant for different dielectric materials.

FIG. 4(a) is a schematic of free standing FE layers and substrate.

FIG. 4(b) is a schematic of an epitaxial bilayer constructed by joining the layers in 4(a) sandwiched between metallic top and bottom electrodes and deposited on a thick substrate.

FIG. 5(a-d) are graphs illustrating the dependence on ST fraction of polarization in BT layer under different external fields.

FIG. 6 is a graph illustrating the relative mean dielectric constant as a function of volume fraction.

FIG. 7(a) is a schematic of a freestanding FE bilayer with equal lateral dimensions.

FIG. 7(b) is a schematic of a FE bilayer constructed by joining the layers in 7(a) sandwiched between metallic top and bottom electrodes.

FIG. 8(a-d) are graphs illustrating free energy potentials as a function of polarization for an equal-fraction BaTiO₃ (BT)-Ba_{0.9}Sr_{0.1}TiO₃ (BST 90/10) bilayer.

FIG. 9(a-d) are graphs illustrating the free energy potentials as a function of polarization for an equal fraction BT-BST 90/10 bilayer on a substrate with in-plane strains.

### DESCRIPTION OF EXEMPLARY EMBODIMENT(S)

The present disclosure provides for a method for designing high capacity and low leakage multilayer stacks and preferably dielectric/ferroelectric/dielectric (DE/FE/DE) stacks for various electronics related applications. Exemplary (DE/FE) stacks can also be designed under the same design criteria as a trilayer stack. An exemplary embodiment associated with the present disclosure includes, but is not limited to, implementation of the DE/FE/DE stacks for dynamic random access memories (DRAMs), on-chip capacitors, on-chip filter elements, high frequency strip lines and waveguides, optical elements found in micro-opto-electro-mechanical systems (MOEMS), Ferroelectric Random Access Memory elements (FeRAMS), and integrated circuit (IC) elements.

DE/FE/DE stacks have been shown to offer giant dielectric permittivity which, in certain embodiments, may be at least two orders of magnitudes higher than conventional gate dielectrics. A strong interlayer coupling between the ferroelectric layer and the dielectric layer exists and contributes to the improved results. According to the present disclosure, superior performance can be achieved via tuning the relative layer fraction in the stacks. As the direct contact between the electrodes and the ferroelectric layer is eliminated, the proposed configuration will greatly reduce the leakage and losses, which is a critical issue associated with existing applications.

Typical FE/Electrode configurations yield major charge leakage thus adversely affecting stack performance. In an exemplary configuration associated with the present disclosure, DE/FE/DE stacks can be adapted to substantially eliminate charge leakage. In this embodiment, the FE layer serves as an internal source that polarizes the DE layer below a critical fraction of the DE. When the ferroelectric heterostructure or the multilayer stack is constructed in such a way that the DE layer fraction is close to this critical fraction, the dielectric response of the capacitor device can be improved drastically. Designing stacks having certain layer thickness should be done relative to critical fraction analysis.

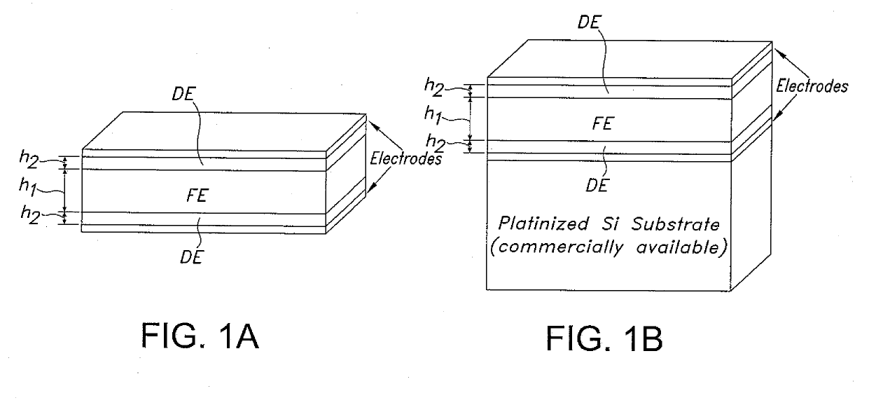

FIG. 1 is a schematic of an exemplary embodiment of a trilayer DE/FE/DE stack consisting of a single ferroelectric layer defining a thickness of h1 sandwiched between two dielectric layers, each defining a thickness of h₂. The relative volume fraction a can be expressed through the thickness of each layer, α=h₂/h. The dielectric layer can be selected from any dielectric material available and/or a combination of dielectric materials. Examples of dielectric materials include, but are not limited to: SrTiO₃ (ST), SiO₂, Si₃N₄, Al₂O₃, Y₂O₃, La₂O₃, Ta₂O₅, TiO₂, HfO₂, ZrO₂, and combinations therein. Examples of ferroelectric materials include but are not limited to: BaTiO₃ (BT), Ba₁₋ₓSrₓTiO₃ (0<x<0.25) (BST), PbTiO₃ (PT), Pb1-xLaxTiO₃ (PLT), Pb1-xZrxTiO₃ (0<x<0.40) (PZT), Pb(Zn_{1/3}Nb_{2/3})O₃ (PZN), Pb(Mg_{1/3}Nb_{2/3})O₃ (PMN), Sr₁₋ₓBaₓNb₂O₆ (SBN), Bi₄Ti₃O₁₂, Bi₄₋ₓLaₓTi₃O₁₂, SrBi₂Ta₂O₉ (SBT), BaBi₄Ti₅O₁₈, BiFeO₃, KNO₃, LiNbO₃, LiTaO₃, and combinations therein.

The following expressions illustrate exemplary methods associated with the present disclosure for quantitatively solving for optimal design and parameters of a DE/FE/DE stack. In general, the free energy density of each layer can be written as:

$${F}_{i} ( {P}_{i} ) = {F}_{0 , i} + \frac{1}{2} {a}_{i} {P}_{i}^{2} + \frac{1}{4} {b}_{i} {P}_{i}^{4} + \frac{1}{6} {c}_{i} {P}_{i}^{6} \qquad ( 1 )$$

where aᵢ, bᵢ and cᵢ are Landau coefficients of bulk material with aᵢ=(T-T_{C,i})/ε₀Cᵢ where ε₀ is the permittivity of free space, T_{C,i} and Cᵢ are the Curie-Weiss temperature and constant of layer i. The spontaneous polarization in the FE layers (P_{0,i}) is given by the equation of state ∂Fᵢ/∂Pᵢ=0.

Due to interlayer coupling, the internal electric field can be derived through the Maxwell relation:

$$\begin{matrix}{E}_{D , 1} = \frac{2 α}{{ɛ}_{0}} ( {P}_{2} - {P}_{1} ) , & ( 2 ) \\ {E}_{D , 2} = \frac{1 - 2 α}{{ɛ}_{0}} ( {P}_{1} - {P}_{2} ) . & ( 3 )\end{matrix}$$

Therefore the total free energy takes the form:

$${F}_{Σ} = ( 1 - 2 α ) [ {F}_{1} ( {P}_{1} ) - {EP}_{1} ] + 2 α [ {F}_{2} ( {P}_{2} ) - {EP}_{2} ] + \frac{1}{2} \cdot 2 α ( 1 - 2 α ) \frac{1}{{ɛ}_{0}} {( {P}_{1} - {P}_{2} )}^{2} + \frac{{F}_{S}}{h} \qquad ( 4 )$$

where F_{S} is the energy per unit area of interlayer interface and is polarization independent.

The equilibrium polarization in each layer is given by the simultaneous solution of the equations of state ∂F_{Σ}/∂Pᵢ=0. The (small-signal) average relative dielectric response can be defined as:

$$< {ɛ}_{R} > ≅ \frac{1}{{ɛ}_{0}} \frac{ⅆ < P >}{ⅆ E} = \frac{1}{{ɛ}_{0}} [ ( 1 - 2 α ) \frac{δ {P}_{1}}{E} + 2 α \frac{δ {P}_{2}}{E} ] \qquad ( 5 )$$

where δPᵢ=Pᵢ(E)−Pᵢ(E=0) as E→0 and Pᵢ satisfying the equilibrium conditions ∂F_{Σ}/∂Pᵢ=0.

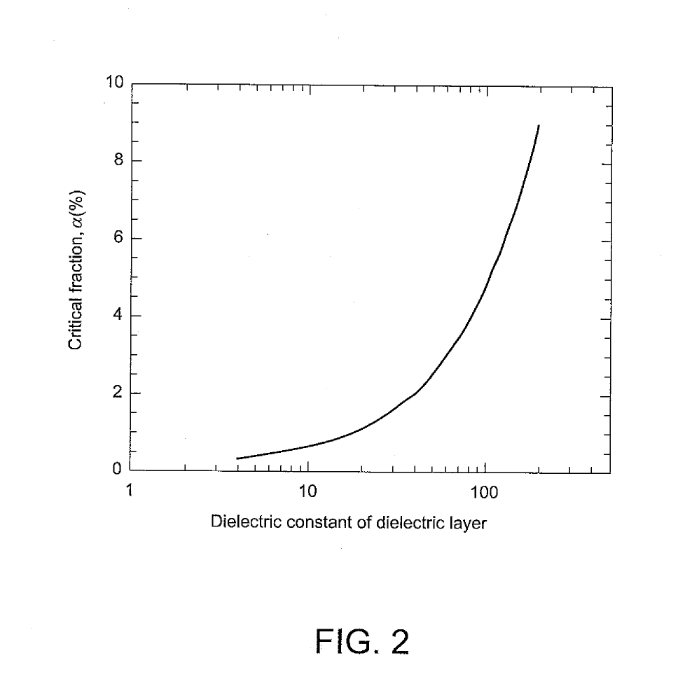

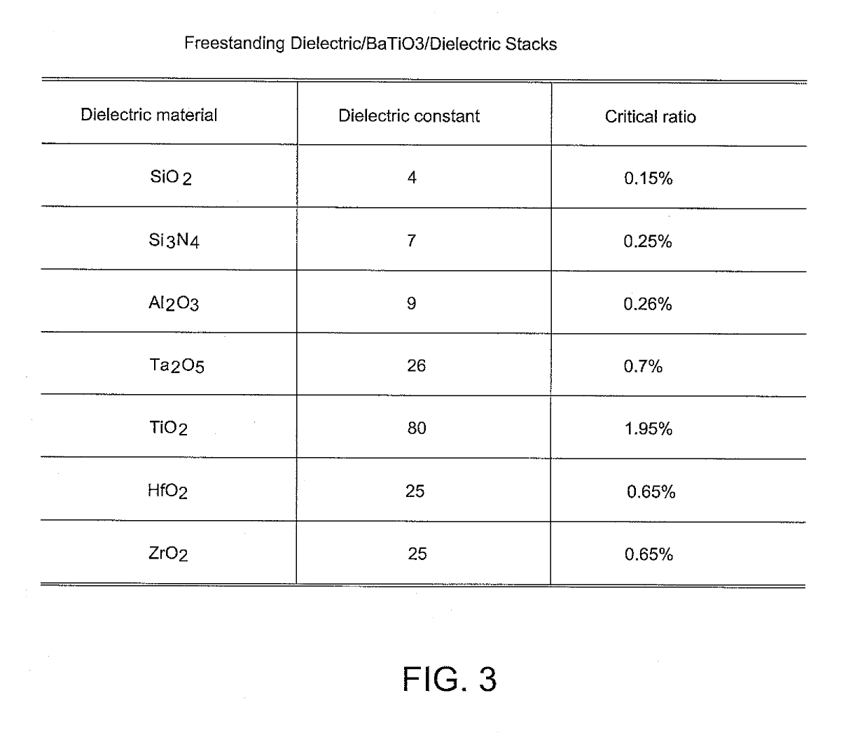

Based on the expressions described above, a critical fraction of dielectric layer exists where the trilayer has maximum dielectric response. This critical fraction varies for different dielectric materials depending on their dielectric constant, as shown in FIG. 2. FIG. 3 is a chart correlating dielectric constants with critical fraction α. Using this chart, a trilayer stack can be designed having desired properties for different amounts of dielectric materials relative to ferroelectric material.

This configuration of a FE layer sandwiched between DE layers will also reduce the leakage and losses in the stack as the direct contact between the metal electrodes and the FE layer is eliminated. Therefore, such a configuration would simultaneously maximize the dielectric response and minimize the dielectric losses. A DE/FE/DE configuration yields strong electrostatic coupling as described by the examples below.

In an exemplary embodiment associated with the present disclosure, a multilayer stack is a trilayer stack wherein the DE layers are of the same material and the same height. In an exemplary embodiment, a multilayer stack can be designed such that the DE layers are of different material and/or have different thickness. The design method described above is capable of designing a multilayer stack having different DE materials and/or thickness by solving for a critical fraction a by taking into account electrostatic interaction between each individual layer. Thus, rather than using α to solve for h₂, the thickness of the dielectric layer, α is used to solve for h₁, the thickness of the ferroelectric layer via the equation 1−α=h₁/h, wherein h=h₁+h₂+h₃.

In an exemplary embodiment, a multilayer stack associated with the present disclosure has multiple layers within each DE/FE/DE layer. Thus, a plurality of DE materials can be used to create each of the DE layers. Likewise, a plurality of FE layers can be used to create the FE layer. The design method described above is capable of designing a multilayer stack having several layers of each material by taking into account the electrostatic interaction between each individual layer.

Electrical devices associated with the present disclosure exhibit advantageous properties including reduced leakage loss and increased DE constants. In an exemplary embodiment, a multilayer stack associated with the present disclosure achieves leakage loss at or below 0.1. A stack associated with the present disclosure also has a dielectric constant of at least 500. In an exemplary embodiment the dielectric constant is greater than 500. In a further exemplary embodiment, the dielectric constant is greater than 1500.

To further illustrate the uses and advantages associated with the disclosed systems and methods, reference is made to the following examples. However, it is to be understood that such examples are not limiting with respect to the scope of the present disclosure, but are merely illustrative of exemplary implementations and/or utilities thereof.

### Example 1

The present disclosure relates to a thermodynamic model that at least in pertinent part describes the polarization and the dielectric response of ferroelectric-paraelectric bilayers and multilayers. Paraelectric layers can be dielectric materials. A strong electrostatic coupling between the layers typically results in the suppression of ferroelectricity at a critical paraelectric layer thickness. The bilayer is expected to have a gigantic dielectric response similar to the dielectric anomaly near Curie-Weiss temperature in homogeneous ferroelectrics at the determined critical thickness. A numerical analysis is carried out for a pseudomorphic BaTiO₃/SrTiO₃ heteroepitaxial bilayer on SrTiO₃ and a stress-free BaTiO₃/SrTiO₃ bilayer. Complete polarization suppression and a dielectric peak are predicted to occur at approximately 66% and 14% of SrTiO₃ in these two systems, respectively.

Ferroelectric (FE) multilayers, superlattices, and graded ferroelectrics have attracted considerable interest in recent years due to their dramatically different behavior compared to their constituents in bulk form. Indeed, multilayer and graded FE's exhibit many striking phenomena and properties, including substantial variations in phase transition characteristics, an enhancement in remnant polarization, and a large dielectric response. Experimental observations and theoretical studies clearly suggest that there is a strong interlayer coupling of the layers that must be considered to account for the properties of FE heterostructures. However, there are no systematic investigations directed to the effect of electrostatic interactions on the interlayer coupling.

This example presents a thermodynamic analysis explicitly taking into account electrostatic interactions between FE-FE and FE-paraelectric (PE) bilayers. For a FE-PE bilayer, the analysis predicts the presence of a critical relative thickness at which a gigantic dielectric response, similar to the λ-type response at transition temperature, is expected.

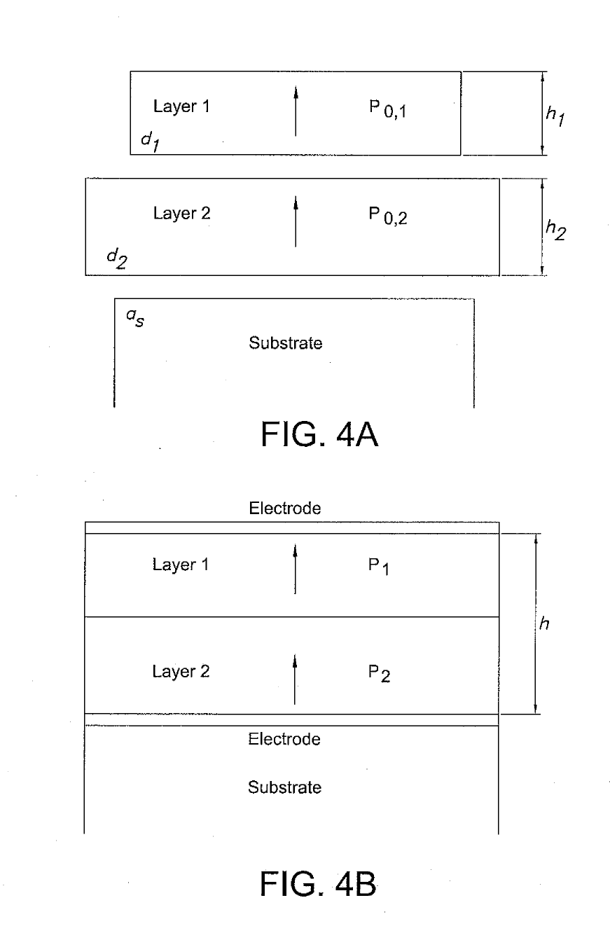

Consider a bilayer of two FE layers between electrodes on a substrate much thicker than the bilayer as shown with respect to FIGS. 4(a)-4(b). A multilayer consisting of sets of identical bilayers on a thick substrate with the same short circuit conditions can be considered analogously. The free energy density of the bilayer (or the multilayer) can be presented as follows:

$$F = ( 1 - α ) [ {F}_{1} ( {P}_{1} ) - {EP}_{1} ] + α [ {F}_{2} ( {P}_{2} ) - {EP}_{2} ] + \frac{1}{2} α ( 1 - α ) \frac{1}{{ɛ}_{0}} {( {P}_{1} - {P}_{2} )}^{2} + \frac{{F}_{S}}{h} , \qquad ( 6 )$$

where α=h₂/h (h=h₁+h₂) is the relative thickness of the layers, Pᵢ is the polarization of layer i normal to the interlayer interface, and E is an applied electrical field parallel to the polarization. The third term with the coefficient α(1−α) expresses the electrostatic coupling between the layers. Fᵢ(Pᵢ) are the uncoupled free energies of the layers that can be determined by a Landau expansion, such that

$${F}_{i} ( {P}_{i} ) = {F}_{0 , i} + \frac{1}{2} {a}_{i} {P}_{i}^{2} + \frac{1}{4} {b}_{i} {P}_{i}^{4} + \frac{1}{6} {c}_{i} {P}_{i}^{6} . \qquad ( 7 )$$

The normalized coefficients aᵢ and bᵢ are used to take into account the misfit between the layers and substrate and the two-dimensional clamping effect of the substrate,

$${a}_{i} = {a}_{i}^{0} - {x}_{i} \frac{4 {Q}_{12 , i}}{{S}_{11 , i} + {S}_{12 , i}} , {b}_{i} = {b}_{i}^{0} + {x}_{i} \frac{4 {Q}_{12 , i}^{2}}{{S}_{11 , i} + {S}_{12 , i}} , \qquad ( 8 )$$

where S_{ij,i} and Q_{ij,i} are the elastic compliances at constant polarization and electrostrictive coefficients of layer i, respectively; xᵢ=(a_{S}−dᵢ)/a_{S} is the in-plane misfit strain of layer i with respect to substrate, where dᵢ is the unconstrained equivalent cubic cell constants of layer i and a_{S} is the lattice parameter of the substrate. For a pseudomorphic bilayer, these misfit strains are not independent and the relation between them is given by x₂=1−[d₂(1−x₁)/d₁]; aᵢ⁰ and bᵢ⁰ are Landau coefficients of bulk material with a aᵢ⁰=(T−T_{C,i})/ε₀Cᵢ where ε₀ is the permittivity of free space, T_{C,i} and Cᵢ are the Curie-Weiss temperature and constant of layer i. The spontaneous polarization in the FE layers (P_{0,i}) is given by the equation of state ∂Fᵢ/∂Pᵢ=0.

The last term in Equation (6) is the energy of the interfaces between the layers and assumes that the layers are relatively thick compared to the correlation length of ferroelectricity which is of the order of 1 nm. Therefore, the interface energy F_{S}/h (even for thin bilayers with thickness of about 100 nm) can be neglected. The polarization is given by the continuity of the normal component of the electrical displacement across the interfaces in each layer. The polarizations beyond the interface area are constant in each layer. Similarly, the internal stresses arising from the misfit between the films and the substrate are homogeneously distributed throughout the volume of the individual layers if these layers are free of dislocations and other defects.

The polarizations in the coupled layer are determined by the equation of equilibrium ∂F/∂P₁=∂F/∂P₂=0

$$\frac{ⅆ {F}_{1}}{ⅆ {P}_{1}} = E + \frac{α}{{ɛ}_{0}} ( {P}_{2} - {P}_{1} ) , \frac{ⅆ {F}_{2}}{ⅆ {P}_{2}} = E + \frac{1 - α}{{ɛ}_{0}} ( {P}_{1} - {P}_{2} ) , \qquad ( 9 )$$

where the second terms in the right part of Equations (9) are the depolarizing fields in the layers, E_{D,1} and E_{D,2}, which arise due to mismatch of the equilibrium polarization of constrained and uncoupled layers, P_{0,1}−P_{0,2}(P_{0,1}>P_{0,2}).

The role of the internal fields is significantly different for layers 1 and 2. In layer 2 E_{D,2}>0 enhances the polarization and increases stability of a FE state. Alternatively, E_{D,1} is negative, meaning that the field is directed opposite to the spontaneous polarization and thus decreases stability of the FE state in layer 1. The destabilization effect of depolarizing field in layer 1 is maximum if P_{0,2}=0, i.e., for a FE-PE bilayer.

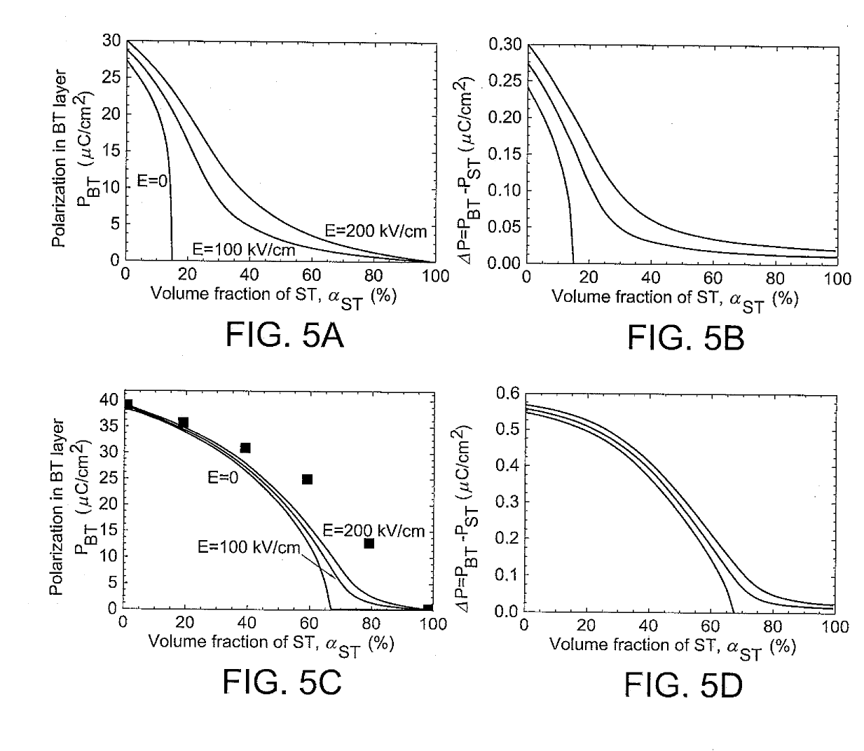

Equations (9) have been solved for this particular case taking as an example BaTiO₃ (BT) and SrTiO₃ (ST) as the FE and PE layers, respectively. The Landau coefficients and elastic constants for BT and ST are well established and allow for a numerical quantitative study. A heteroepitaxial ST-BT bilayer on a thick ST substrate such that x_{ST}=0% in Equation (8) at RT is considered. The lattice parameters of ST and BT are 0.3905 and 0.3994 nm, respectively, and thus the strain in the BT layer is x_{BT}=−2.28%. The equilibrium polarization of a BT film at this strain level is 38 μC/cm². The spontaneous polarization in the BT layer in the ST-BT bilayer for E=0 decreases from this value with increasing volume fraction of the ST layer until it completely vanishes at a critical relative thickness of α_{ST}=0.66 [FIG. 5(a)]. FIG. 5(b) plots the difference between polarizations in the coupled BT and ST layers ΔP=P_{BT}−P_{ST}. ΔP is small (typically less than 1% of the polarization of BT) indicating that the induced polarization in the ST layer almost equals the polarization in BT layer.

As the relative fraction of the ST layer increases, there is a commensurate rise in the depoling field in the BT layer as well as a drop in the internal field in the ST layer that induces polarization. Eventually, a critical relative thickness is reached at α_{ST}=0.66 which corresponds to P₁=P₂=0, the only solutions of Equations (9) for α_{ST}≧0.66. The equilibrium polarization in BT layer and the polarization difference between two layers for a completely relaxed system has similar behavior as shown in FIGS. 5(c) and 5(d). Without the biaxial internal stress, the polarization in the BT is ˜27 μC/cm² for α_{ST}≈0 and disappears at a critical relative thickness, α_{ST}=0.14.

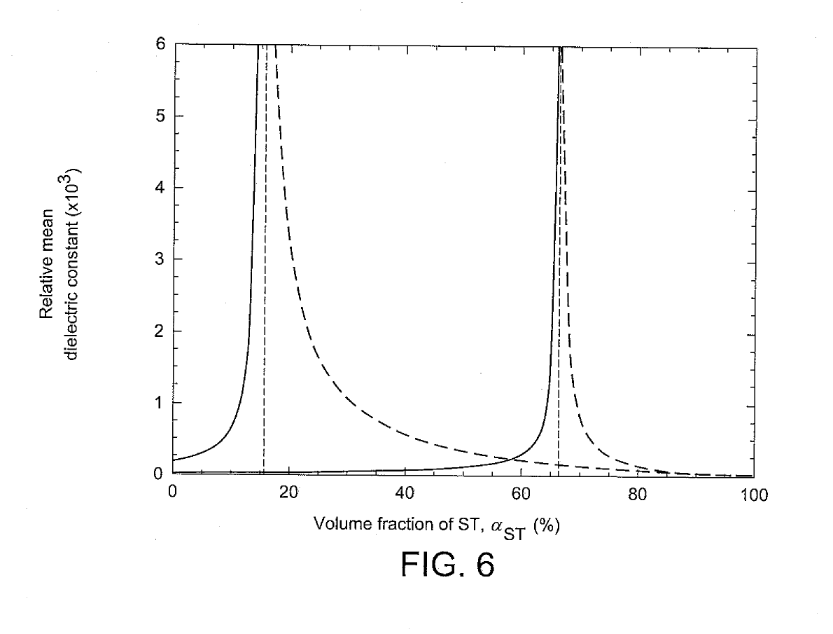

The (small-signal) average dielectric response of the bilayer is

$$< {ɛ}_{0} > ≅ \frac{1}{{ɛ}_{0}} \frac{ⅆ < P >}{ⅆ E} = \frac{1}{{ɛ}_{0}} [ ( 1 - α ) \frac{δ {P}_{1}}{E} + α \frac{δ {P}_{2}}{E} ] , \qquad ( 10 )$$

where <P>=(1−α)P₁+αP₂ is the average polarization, δPᵢ=Pᵢ(E)−Pᵢ(E=0) as E→0, and Pᵢ satisfying Equations (9). The dielectric response of the heteroepitaxial and unconstrained BT-ST bilayers are shown with respect to FIG. 6 and display an anomaly at the critical relative thicknesses.

To explain the behavior of polarization and dielectric constant of a bilayer, analytical solutions of Equations (9) are considered. Using a linear approximation for internal field of layer 2 such that dF₂/dP₂=−2a₂(P₂−P_{0,2}) for a₂<0 (FE state) or dF₂/dP₂=a₂P₂ for a₂>0 (PE state) together with the approximation
dF₁/dP₁=a₁P₁+b₁P₁³ (11)
transform Equation (9) into

$$\frac{1}{2 {ɛ}_{1}} [ - {P}_{1} ( 1 - \frac{2 {ɛ}_{1} α}{1 + ( 1 - α ) {ɛ}_{2}} ) + \frac{{P}_{1}^{3}}{{P}_{0 , 1}^{2}} ] = \frac{α {P}_{0 , 2}}{1 + ( 1 - α ) {ɛ}_{2}} , \qquad ( 12 )$$

where P_{0,1}²=−a₁/b₁, ε₁=−1/(2ε₀a₁), and ε₂=−1/(2ε₀a₂), [or ε₂=1/(e₀a₂) in the PE state] are the dielectric constants of the constitutive layers. For a FE-PE bilayer P_{0,2}=0 and thus

$${P}_{1} = \pm {P}_{0 , 1} \sqrt{1 - \frac{2 {ɛ}_{1} α}{1 + ( 1 - α ) {ɛ}_{2}}} , \qquad ( 13 )$$

which vanishes at a critical relative thickness a*=(1+ε₂)/(2ε₁+ε₂) that results in <P>=0. For a FE-FE bilayer, P₁ decreases but does not disappear for all fractions of layer 2 since P_{0,2}>0.

The analogy with temperature dependence of polarization and dielectric response as well as with smearing of the dielectric anomaly under an applied electric field is apparent (FIGS. 5(a)-5(d)). However, the effect of the depolarizing field is not equivalent to the effect of temperature. Therefore, using the expansion of free energy [Equation (11)] does not mean that the phase transition in bulk ferroelectrics is a second order transformation.

For example, BT in a constrained layer undergoes a second order phase transformation, while in bulk BT the transformation is first order. Although a single-domain state near the transformation temperature is unstable with respect to the formation of 180° domains, it can be metastable far from this temperature, especially for thin constrained FE films. Independent analysis in bilayers with results of first principal calculations for superlattices allows conclusions that the effects of electrostatic interactions considered above should be observed in thin films as well. The polarization of superlattices with period equaling five atomic planes shown in FIG. 5(a) demonstrates a similar dependence on the layer fraction as a macroscopic FE-PE bilayer. A critical fraction of −0.9 can be expected on the basis of extrapolation of microscopic data to the zero polarization [dashed line in FIG. 5(a)]. Indeed, it is apparent that increasing the period of the superlattices should decrease the deviation between the results of macroscopic and microscopic analysis.

Experimental results provide support for several conclusions discussed herein. Experimental observations where an average relative dielectric response of ˜500 was demonstrated for a BT-ST superlattice with ε_{ST}=0.5 and one stacking period can be related to the properties of a partially relaxed bilayer. Extremely high dielectric permittivities in PbTiO₃—Pb₁₋ₓLaₓTiO₃ and SrZrO₃—SrTiO₃ superlattices have been reported in the literature that are also in agreement with the conclusions herein.

Free charges that may be present in bilayers in thin-film form result in a similar effect as the misfit dislocations as they “relax” (or compensate for) bound charges at the interlayer interfaces. Their contribution can be included in the thermodynamic model using a “correction factor,” the ratio of the free charge to bound charge density at the interlayer interface, in the internal fields of Equations (9).

The electrostatic interlayer coupling described with respect to exemplary embodiments herein has significant technological implications. First, an extremely high dielectric response can be achieved in the vicinity of a critical layer fraction. In addition, below the critical layer fraction it is possible to induce almost as much polarization in the PE layer as the FE layer, and the bilayer displays FE behavior in the absence of an applied electric field. The leakage and loss characteristics of FE devices could, therefore, be controlled by depositing thin PE or dielectric buffer layers that would not result in a decrease in the overall polarization and the dielectric response. This is consistent with results where the loss of ferroelectric memory elements have been shown experimentally to be reduced by growing top and bottom dielectric buffers before they were metallized.

### Example 2

Compositional variations across ferroelectric bilayers result in broken spatial inversion symmetry that can lead to asymmetric thermodynamic potentials. For the case of insulating materials, ferroelectric multilayers will self-pole due to the electrostatic coupling between the layers. Polarization-graded ferroelectrics with smooth composition, temperature, or stress gradients are viewed as bilayer structures in the limit of the ever-increasing number of bilayer couples, thus concluding that the unconventional hysteresis associated with “up” and “down” polarization graded structures are real phenomena, and not artifacts associated with free charge or asymmetric leakage current.

Significant time has passed since an unconventional form of hysteresis was first observed and characterized from polarization-graded ferroelectrics (FE's). Subsequently, it was concluded that the offsets observed from “up” and “down” graded materials were the result of “built-in” potentials due to the polarization gradients; (analogous to the potentials that account for the asymmetric conduction observed from semiconductor junction devices). Successive theoretical refinements of these concepts starting first with a simple Slater model, followed by a transverse Ising model electrostatic analysis, and finally detailed thermodynamic modeling have yielded progressively better descriptions for these internal potentials, the latter of which can completely account for most of the experimental observations related to the structures without any free “fitting” parameters. However, despite a long succession of theoretical and experimental papers aimed at conclusively showing that the observed properties are a direct result of the polarization gradients, controversy still persists as to the role of free charge or asymmetric leakage current in determining the hysteretic response of polarization graded structures.

Thus, FE bilayers having differing levels of intrinsic polarization and permittivity were examined. Specifically, the results described herein show that even in the absence of free charges, a polarization difference between the two layers skews the otherwise symmetric potentials of the constituent FE materials, thereby breaking the spatial symmetry of the potentials and making it more energetically favorable for the FE bilayers to self-pole. The findings are entirely consistent with first principles calculations that also revealed asymmetric potentials from inhomogeneous ferroelectric structures.

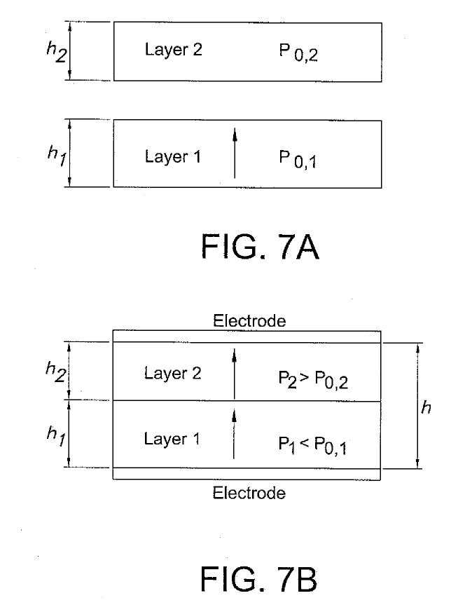

Consider a bilayer consisting of two FE layers with equal lateral dimensions sandwiched between electrodes as shown with respect to FIG. 7(a). A FE superlattice consisting of sets of identical bilayers with the same short-circuit conditions can be treated analogously. In its most general form, the energy density of Layers 1 and 2 in their uncoupled unconstrained state can be expressed as:

$${F}_{ 1} = {F}_{ 0 , 1} + \frac{1}{ 2} {aP}_{ 1}^{ 2} + \frac{1}{ 4} {bP}_{ 1}^{ 4} + \frac{1}{ 6} {cP}_{ 1}^{ 6} , \\ {F}_{ 2} = {F}_{ 0 , 2} + \frac{1}{ 2} {dP}_{ 2}^{ 2} + \frac{1}{ 4} {eP}_{ 2}^{ 4} + \frac{1}{ 6} {fP}_{ 2}^{ 6} , \qquad ( 14 )$$

where F_{0,i} is the energy of layer i in its high-temperature paraelectric state, Pᵢ are the polarizations of Layers 1 and 2, and a, b, c, d, e, and f are Landau coefficients. Coefficients a and d are temperature dependent with their temperature dependency given by the Curie-Weiss law, i.e., a=(T−T_{C,1})/ε₀C₁ and d=(T−T_{C,2})/ε₀C₂ where ε₀ is the permittivity of free space, T_{C,i} and Cᵢ are the Curie-Weiss temperature and constant of Layer i. The other coefficients for both materials are assumed to be temperature independent. The spontaneous polarization for each layer (P_{0,i}) is given by the condition of thermodynamic equilibrium, ∂Fᵢ/∂Pᵢ=0.

Suppose Layer 1 with thickness h₁ is joined together with Layer 2 with thickness h₂ and the bilayer is sandwiched between metallic electrodes [FIG. 7(b)]. The relative volume fraction of Layer 2 is a=h₂/h. Assume that both h₁ and h₂ are much larger than the characteristic correlation lengths of each layer. Before Layers 1 and 2 are brought together, their polarizations are equal to their bulk values P_{0,1} and P_{0,2}. When these layers are coupled, the actual polarization of each layer is expected to be different from its “decoupled” value due to the electrical interaction between the layers. The internal electric fields E_{D,1} and E_{D,2} in Layers 1 and 2 due to the polarization mismatch essentially establish new polarization states, i.e., P₁ and P₂ in Layers 1 and 2, respectively (see FIG. 7(b)). The internal electric fields E_{D} are related to the difference in polarization of each layer and can be determined through the Maxwell relations ∇×E_{D}=0 and ∇×E_{D}=(1/ε₀)(ρ_{f}−∇·P), where ρ_{f}, is the free charge density. For perfectly insulating bilayers, the internal fields in each layer are given by

$$\begin{matrix}{E}_{D , 1} = \frac{1}{{ɛ}_{0}} ( {P}_{1} - 〈 P 〉 ) = \frac{α}{{ɛ}_{0}} ( {P}_{2} - {P}_{1} ) , & ( 15 ) \\ {E}_{D , 2} = \frac{1}{{ɛ}_{0}} ( {P}_{2} - 〈 P 〉 ) = \frac{1 - α}{{ɛ}_{0}} ( {P}_{1} - {P}_{2} ) , & ( 16 )\end{matrix}$$

where [symbol] P [symbol] =(1−α)P₁+αP₂ is the average polarization.

The role of the internal fields is different for Layers 1 and 2. E_{D,2}>0 serves to enhance the polarization of Layer 2. On the other hand, E_{D,1} attempts to decrease the polarization of Layer 1 since it lies antiparallel to the polarization vector (E_{D,1}<0). Therefore, in equilibrium, it is expected that P₁<P_{0,1} and P₂<P_{0,2} so as to decrease the polarization difference, ΔP=P₁−P₂.

The total free energy functional incorporating the potential energies of the internal fields E_{D,1} and E_{D,2} is given by:

$${F}_{\sum } = ( 1 - α ) [ {F}_{1} ( {P}_{1} ) - \frac{1}{2} ξ {E}_{D , 1} {P}_{1} ] + \\ α [ {F}_{ 2} ( {P}_{ 2} ) - \frac{1}{ 2} ξ {E}_{ D , 2} {P}_{ 2} ] + \frac{{F}_{s}}{h} , \\ = ( 1 - α ) {F}_{1} ( {P}_{1} ) + α {F}_{2} ( {P}_{2} ) + \\ \frac{1}{2} α ( 1 - α ) \frac{ξ}{{ɛ}_{0}} {( {P}_{1} - {P}_{2} )}^{2} + \frac{{F}_{s}}{h} , \qquad ( 17 )$$

where F_{S} is the energy per unit area of interlayer interface. This additional contribution may arise, for example, due to the compositional inhomogeneity, the polarization discontinuity, and internal stresses. The effect of the interface extends over very small length scales and since the surface energy scales with the total bilayer thickness, its contribution to the total free energy can be neglected for a relatively thick bilayer.

In Equation (17), a coefficient is introduced which is essentially a measure of the free charge density with respect to the bound charge at the interlayer interface such that ξ=1−ρ_{f}/ρ_{b}, where ρ_{b} is the bound charge density. The two limiting values, ξ=1 and ξ=0 correspond to perfect insulating and semiconducting FE bilayers, respectively. The latter condition implies that there are sufficient free charges with high mobility to compensate for the internal fields due to the polarization mismatch. Thus, for ξ=0 (and for ξ<0), there is no electrostatic contribution to the total free energy due to the internal electrical field.

The equilibrium polarization of each layer is given by the simultaneous solution of the equations of state ∂F_{Σ}/∂P₁=0, and ∂F_{Σ}/∂P₂=0. The thermodynamic potential for each layer can be extracted from the total free energy as:

$$\begin{matrix}{F}_{ 1} ( {P}_{1} ) = {F}_{ 0 , 1} + \frac{1}{ 2} {aP}_{ 1}^{ 2} + \frac{1}{ 4} {bP}_{ 1}^{ 4} + \frac{1}{ 6} {cP}_{ 1}^{ 6} - \frac{1}{2} ξ {E}_{D , 1} {P}_{1} , & ( 18 ) \\ {F}_{ 2} ( {P}_{2} ) = {F}_{ 0 , 2} + \frac{1}{ 2} {dP}_{ 2}^{ 2} + \frac{1}{ 4} {eP}_{ 2}^{ 4} + \frac{1}{ 6} {fP}_{ 2}^{ 6} - \frac{1}{2} ξ {E}_{D , 2} {P}_{2} . & ( 19 )\end{matrix}$$

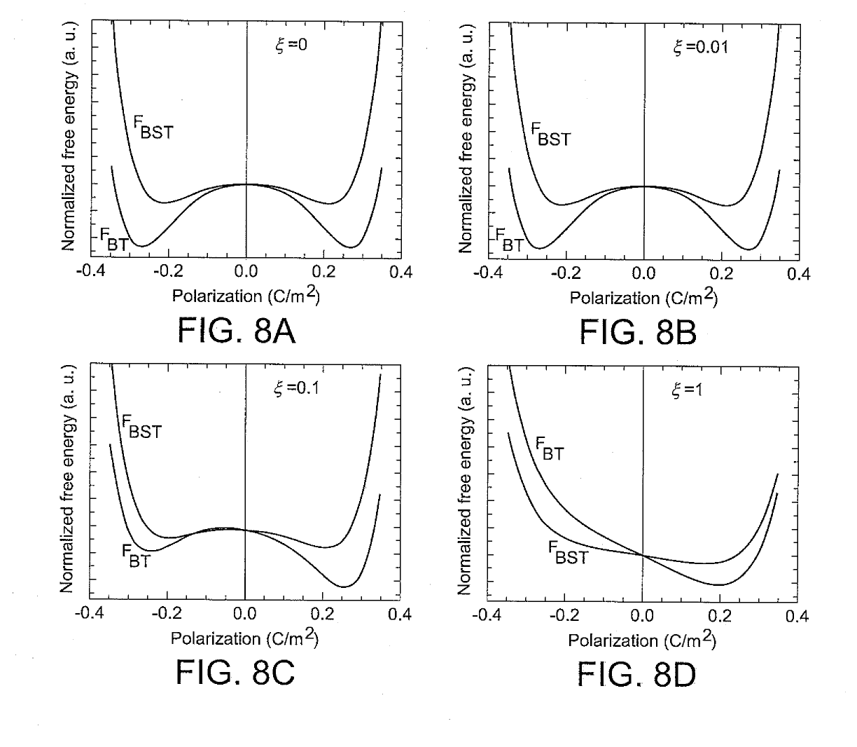

It is clear that the electrostatic energy of the internal fields in Equations (18) and (19) serves to introduce a symmetry breaking element in the otherwise symmetric Landau potentials having even powers of the polarization. Consider the example of an equifraction (α=1/2), stress-free BaTiO₃—Ba_{0.9}Sr_{0.1}TiO₃ (BT-BST90/10) bilayer. In FIGS. 8(a)-8(b), the normalized free energy as a function of the net polarization of each layer is shown. The “degree” of symmetry breaking strikingly varies with the variations in the density of free charges in the bilayer. For instance, for ξ=0 [FIG. 8(a)], the two layers are electrically screened from one another and can act essentially independent and are unrelated entities. This is due to the complete compensation of the electrical field resulting from bound charges at the interlayer interface through free charges. An equivalent construction of this condition would be two ferroelectric layers with a metallic electrode between them, i.e., two dielectrics with a series connection.

Both layers display typical symmetric double well potentials, whose minima correspond to two energetically identical FE ground states. The equilibrium polarizations of the layers assume their values in single-crystal form. Due to the free charges, a relatively large polarization difference, ΔP, can be maintained between the two layers, where, for instance, ΔP=0.056 C/m² for BT-BST90/10 bilayer.

The electric coupling between layers due to the polarization mismatch is evident for nonzero values of ξ where this coupling is enhanced with increasing ξ, i.e., a reduction in the free charges. FIGS. 8(b)-8(d) show that the otherwise symmetric double wells of BT and BST90/10 are skewed toward one FE equilibrium state with P>0. The other FE ground state with P<0 becomes metastable. The strongest value of electrical coupling between the layers corresponds to a bilayer made up of two completely insulating FE's, i.e., no free charges, ξ=1. This results in only one stable FE ground state in both layers and a small polarization difference between two layers (ΔP=0.037 C/m²). The other FE ground state becomes unstable due to the electrical interaction between the layers. This shows that the initial “uncoupled” polarization gradient in insulating graded FE's becomes smoother due to the electrostatic interactions between the layers thus resulting in a smaller polarization difference that seeks to minimize the internal electric field.

The analysis can be extended to a heteroepitaxial bilayer grown on a thick cubic substrate by incorporating the elastic energy of the internal stresses that results in renormalized Landau coefficients:

$$\begin{matrix}\overline{a} = a - {x}_{1} \frac{4 {Q}_{12 , 1}}{{S}_{11 , 1} + {S}_{12 , 1}} , \overline{b} = b + \frac{4 {Q}_{12 , 1}^{2}}{{S}_{11 , 1} + {S}_{12 , 1}} , & ( 20 a ) \\ \overline{d} = d - {x}_{2} \frac{4 {Q}_{12 , 2}}{{S}_{11 , 2} + {S}_{12 , 2}} , \overline{e} = e + \frac{4 {Q}_{12 , 2}^{2}}{{S}_{11 , 2} + {S}_{12 , 2}} , & ( 20 b )\end{matrix}$$

where S_{ij,i} and Q_{ij,i} are the elastic compliances at constant polarization and electrostrictive coefficients of material i, respectively. Variables xᵢ=(a_{S}−aᵢ)/a_{S} are the (polarization-free) misfit strains of layer i with respect to substrate, where aᵢ are the unconstrained equivalent cubic cell constants of layer i and a_{S} is the lattice parameter of the substrate. For a pseudomorphic bilayer with h<h_{ρ} where h_{ρ} is the critical thickness for misfit dislocations, these misfit strains are not independent and the relation between them is given by x₂=1−[a₂(1−x₁)/a₁].

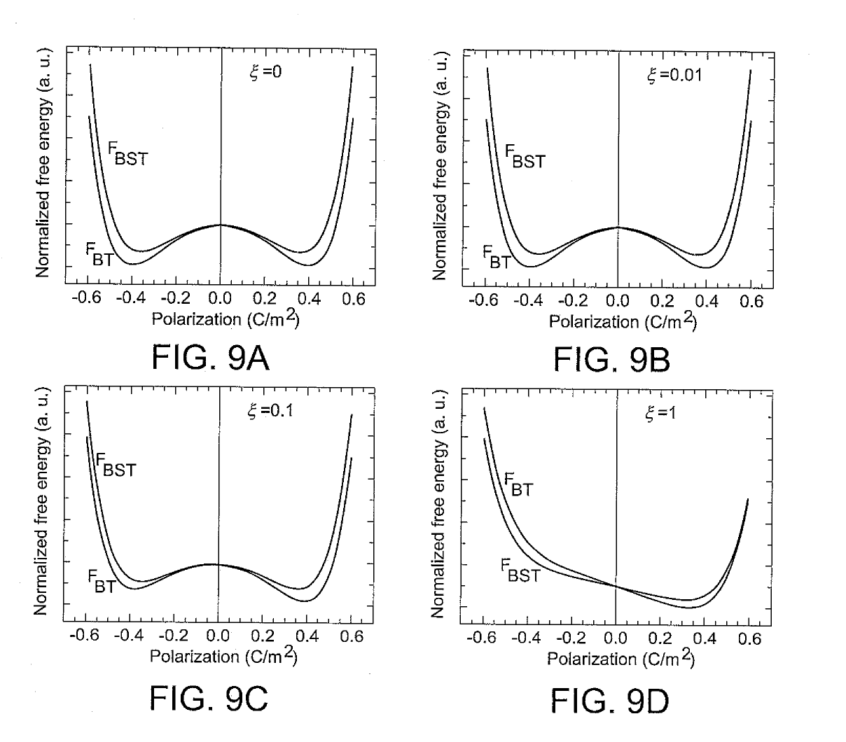

As an example, consider a heteroepitaxial, equifraction BT-BST90/10 bilayer on a SrTiO₃ (ST) substrate. The lattice parameters of ST, BT, and BST are 0.3905 nm, 0.4005 nm, and 0.3999 nm, respectively, and thus the in-plane strains in each layer are x_{BT}=−2.6% and x_{BST}=−2.2%. The equilibrium polarizations of the BT and BST90/10 thin films at these strain levels are 0.39 C/m² for BT and 0.36 C/m² for BST. Similar to the behavior of an unconstrained system, the normalized free energy of both layers as function of polarization is plotted in FIGS. 9(a)-9(d). Due to the small initial polarization difference, the electrostatic coupling effect is not as strong as stress-free layers (FIG. 8) but it still displays electrostatic coupling that induces symmetry breaking.

The results discussed hereinabove are consistent with both the ab initio and density functional theory calculations carried out by Sai et al. concluding that compositional variations result in a broken inversion symmetry that likewise leads to asymmetric thermodynamic potentials. (see e.g. N. Sai, B. Meyer, and D. Vanderbilt, Phys. Rev. Lett. 84, 5636 (2000), N. Sai, K M Rabe, and D. Vanderbilt, Phys. Rev. B 66, 104108 (2002)). As discussed in the present disclosure, whenever the free charge density is less than the bound charges density, an internal potential arises from the compositional inhomogeneity always resulting in asymmetric potentials. Moreover, this allows for expansion beyond the parameters discussed herein by further including the effects of internal stresses in epitaxial films as well as the effects of free charge within material systems. This can lead to a more detailed study extending the analysis to the electrical and electromechanical properties of multilayer and graded FE's incorporating formation of misfit dislocations at the interlayer interfaces. Finally, these results lead to the conclusion that insulating FE multilayers are self-poled due to the electrostatic coupling between the layers.

In sum, the systems and methods of the present disclosure offer significantly enhanced techniques for designing multilayer dielectric stacks for various electronic applications.

Although the present disclosure has been described with reference to exemplary embodiments and implementations thereof, the disclosed systems and methods are not limited to such exemplary embodiments/implementations. Rather, as will be readily apparent to persons skilled in the art from the description provided herein, the disclosed systems and methods are susceptible to modifications, alterations and enhancements without departing from the spirit or scope of the present disclosure. Accordingly, the present disclosure expressly encompasses such modification, alterations and enhancements within the scope hereof.

What is claimed:

1. A method for designing a high capacity low-leakage stack, comprising the steps of:
(a) selecting a dielectric material having a dielectric constant;
(b) determining a critical fraction a based on said dielectric constant;
(c) designing a multilayer stack having at least a first dielectric layer including the dielectric material and defining thickness parameter h₂ coupled with at least a first ferroelectric layer defining thickness parameter h₁, said multilayer stack defining thickness parameter h wherein h=h₁+h₂, based on α=h₂/h.

2. The method according to claim 1, wherein said dielectric material includes an insulator material.

3. The method according to claim 1, wherein said multilayer stack is a trilayer having a second dielectric layer wherein said at least first ferroelectric layer is coupled between said at least a first dielectric layer and said second dielectric layer.

4. The method according to claim 3, wherein said second dielectric layer is fabricated from the same material as said a first dielectric layer and defines thickness parameter h₂ such that h=h₁+2h₂.

5. The method according to claim 1, wherein said multilayer stack is positioned and coupled between a first electrode layer and a second electrode layer.

6. The method according to claim 5, wherein direct contact between said ferroelectric layer and at least one of said first electrode layer or said second electrode layer is eliminated.

7. The method according to claim 1, further comprising the step of growing the multilayer stack on a substrate material.

8. The method according to claim 1, wherein the dielectric material is selected from the group consisting of SrTiO₃, SiO₂, Si₃N₄, Al₂O₃, Y₂O₃, La₂O₃, Ta₂O₅, TiO₂, HfO₂, ZrO₂, and combinations therein.

9. The method according to claim 1, wherein said ferroelectric layer includes a ferroelectric material selected from the group consisting of BaTiO₃, Ba₁₋ₓSrₓTiO₃ (0<x<0.25), PbTiO₃, Pb₁₋ₓLaₓTiO₃, Pb₁₋ₓZrₓTiO₃ (0<x<0.40), Pb(Zn_{1/3}Nb_{2/3})O₃, Pb(Mg_{1/3}Nb_{2/3})O₃, Sr₁₋ₓBaₓNb₂O₆, Bi₄Ti₃O₁₂, Bi₄₋ₓLaₓTi₃O₁₂, SrBi₂Ta₂O₉, BaB₄Ti₅O₁₈, BiFeO₃, KNO₃, LiNbO₃, LiTaO₃, and combinations therein.

10. The method according to claim 1, wherein said multilayer stack is applied to any member selected from the group consisting of Dielectric Random Access Memories (DRAMs), on-chip capacitors, high frequency strip lines, high frequency waveguides, micro-opto-electro-mechanical systems (MOEMS), Ferroelectric Random Access Memory elements (FeRAMS), and integrated circuit (IC) elements.

11. The method according to claim 1, wherein said multilayer stack has dielectric permittivity of at least 10.

12. The method according to claim 1, wherein a is determined from an expression defined by:
$${F}_{\sum } = ( 1 - 2 α ) [ {F}_{1} ( {P}_{1} ) - {EP}_{1} ] + 2 α [ {F}_{2} ( {P}_{2} ) - {EP}_{2} ] + \frac{1}{2} \cdot 2 α ( 1 - 2 α ) \frac{1}{{ɛ}_{0}} {( {P}_{1} - {P}_{2} )}^{2} + \frac{{F}_{s}}{h} .$$

13. A multilayer stack comprising:
(a) at least a first dielectric layer including a dielectric material characterized by a dielectric constant, said dielectric layer defining a thickness h₂;
(b) at least one ferroelectric layer including a ferroelectric material coupled to said dielectric layer, said ferroelectric layer defining a thickness h₁;
wherein said dielectric constant yields a critical fraction a; and
wherein h=h₁+h₂ and α=h₂/h; and
wherein said ferroelectric material is selected from the group consisting of BaTiO₃, Ba₁₋ₓSrₓTiO₃ (0<x<0.25), PbTiO₃, Pb₁₋ₓLaₓTiO₃, Pb₁₋ₓZrₓTiO₃ (0<x<0.40), Pb(Zn_{1/3}Nb_{2/3})O₃, Pb(Mg_{1/3}Nb_{2/3})O₃, Sr₁₋ₓBaₓNb₂O₆, Bi₄Ti₃O₁₂, Bi₄₋ₓLaₓTi₃O₁₂, SrBi₂Ta₂O₉, BaB₄Ti₅O₁₈, BiFeO₃, KNO₃, LiNbO₃, LiTaO₃, and combinations therein.

14. The multilayer stack according to claim 13, wherein said dielectric material is an insulator material.

15. The multilayer stack according to claim 14, wherein said ferroelectric layer is coupled between said first dielectric layer and a second dielectric layer.

16. The multilayer stack according to claim 15, wherein said second dielectric layer includes a dielectric material that is the same material as the dielectric material associated with said first dielectric layer and defines a thickness parameter h₂ such that h=h₁+2h₂.

17. The multilayer stack according to claim 13, wherein said at least a first dielectric layer and said at least one ferroelectric layer are incorporated into a member selected from the group consisting of Dielectric Random Access Memories (DRAMs), on-chip capacitors, high frequency strip lines, high frequency waveguides, micro-opto-electro-mechanical systems (MOEMS), Ferroelectric Random Access Memory elements (FeRAMS), and integrated circuit (IC) elements.

18. The multilayer stack according to claim 13, wherein α is determined from an expression defined by:
$${F}_{\sum } = ( 1 - 2 α ) [ {F}_{1} ( {P}_{1} ) - {EP}_{1} ] + 2 α [ {F}_{2} ( {P}_{2} ) - {EP}_{2} ] + \frac{1}{2} \cdot 2 α ( 1 - 2 α ) \frac{1}{{ɛ}_{0}} {( {P}_{1} - {P}_{2} )}^{2} + \frac{{F}_{s}}{h} .$$

19. An electrical device comprising:
a multilayer stack having at least one dielectric layer including a dielectric constant defining a thickness h₂ and at least one ferroelectric layer including a ferroelectric material coupled to said dielectric material defining a thickness h₁;
wherein said dielectric constant yields a critical fraction α;
wherein h=h₁+h₂ and α=h₂/h;
wherein said multilayer stack exhibits a leakage loss less than or equal to 0.01; and
wherein said dielectric constant is polarized to a value of at least 500.

20. The device according to claim 19, wherein said dielectric constant is polarized to a value in the range of 500-1500.

21. The device according to claim 19, wherein said dielectric constant is polarized to a value of at least 1500.

22. The device according to claim 19, wherein said multilayer stack is incorporated into a member selected from the group consisting of Dielectric Random Access Memories (DRAMs), on-chip capacitors, high frequency strip lines, high frequency waveguides, micro-opto-electro-mechanical systems (MOEMS), Ferroelectric Random Access Memory elements (FeRAMS), and integrated circuit (IC) elements.

23. The device according to claim 19, wherein α is determined from an expression defined by:
$${F}_{\sum } = ( 1 - 2 α ) [ {F}_{1} ( {P}_{1} ) - {EP}_{1} ] + 2 α [ {F}_{2} ( {P}_{2} ) - {EP}_{2} ] + \frac{1}{2} \cdot 2 α ( 1 - 2 α ) \frac{1}{{ɛ}_{0}} {( {P}_{1} - {P}_{2} )}^{2} + \frac{{F}_{s}}{h} .$$

24. A multilayer stack comprising:
(a) at least a first dielectric layer including a dielectric material characterized by a dielectric constant, said dielectric layer defining a thickness h₂;
(b) at least a second dielectric layer including a dielectric material characterized by a dielectric constant, said dielectric layer defining a thickness h₃;
(c) at least one ferroelectric layer including a ferroelectric material coupled and positioned therebetween said at least a first dielectric layer and said at least a second dielectric layer, said ferroelectric layer defining a thickness h₁;
wherein said dielectric constants associated with each of said at least a first dielectric layer and said at least a second dielectric layer yield a critical fraction a;
wherein h=h₁+h₂+h₃ and 1−α=h₁/h; and
wherein said ferroelectric material is selected from the group consisting of BaTiO₃, Ba₁₋ₓSrₓTiO₃ (0<x<0.25), PbTiO₃, Pb₁₋ₓLaₓTiO₃, Pb₁₋ₓZrₓTiO₃ (0<x<0.40), Pb(Zn_{1/3}Nb_{2/3})O₃, Pb(Mg_{1/3}Nb_{2/3})O₃, Sr₁₋ₓBaₓNb₂O₆, Bi₄Ti₃O₁₂, Bi₄₋ₓLaₓTi₃O₁₂, SrBi₂Ta₂O₉, BaBi₄Ti₅O₁₈, BiFeO₃, KNO₃, LiNbO₃, LiTaO₃, and combinations therein.

25. The multilayer stack according to claim 24, wherein said at least a first dielectric layer and said at least a second dielectric layer include different dielectric materials with respect to each other and wherein said dielectric materials are insulator materials.

26. The multilayer stack according to claim 24, wherein h₁≠h₃.

27. The multilayer stack according to claim 24, wherein said at least a first dielectric layer, said at least a second dielectric layer and said at least one ferroelectric layer are incorporated into a member selected from the group consisting of Dielectric Random Access Memories (DRAMs), on-chip capacitors, high frequency strip lines, high frequency waveguides, micro-opto-electro-mechanical systems (MOEMS), Ferroelectric Random Access Memory elements (FeRAMS), and integrated circuit (IC) elements.

28. The multilayer stack according to claim 24, wherein α is determined from an expression defined by:
$${F}_{\sum } = ( 1 - 2 α ) [ {F}_{1} ( {P}_{1} ) - {EP}_{1} ] + 2 α [ {F}_{2} ( {P}_{2} ) - {EP}_{2} ] + \frac{1}{2} \cdot 2 α ( 1 - 2 α ) \frac{1}{{ɛ}_{0}} {( {P}_{1} - {P}_{2} )}^{2} + \frac{{F}_{s}}{h} .$$
